(19) United States
(12) Patent Application Publication
(10) Pub. No.: US 2026/0128743 A1
(43) Pub. Date: May 7, 2026

(54) MAGNETIC INDUCTION MICRO SWITCH WITH SELF-CALIBRATION

(71) Applicant: Yueqing Tengfei Electronics Co., Ltd., Wenzhou City (CN)

(72) Inventors: Bo Teng, Shenzhen City (CN); Yuexin Gu, Leiyang City (CN); Teng Teng, Yueqing City (CN); Lingfeng Teng, Yueqing City (CN)

(73) Assignee: Yueqing Tengfei Electronics Co., Ltd., Wenzhou City (CN)

(21) Appl. No.: 19/381,484

(22) Filed: Nov. 6, 2025

(30) Foreign Application Priority Data
Nov. 7, 2024 (CN) 202422705722.9

(51) Int. Cl. H03K 17/90; H01H 13/14; H01H 13/36

(52) U.S. Cl. CPC H03K 17/90; H01H 13/14; H01H 13/36

(57) ABSTRACT

The present application discloses a magnetic induction micro switch with self-calibration. The micro switch includes a base provided on a printed circuit board (PCB), a housing cooperating with the base to form an installation cavity, a spring sheet installed in the installation cavity of the base via a conductive support, a limiting frame connected to a movable end of the spring sheet, and an operating member cooperating with the spring sheet and partially extending out of the housing. The spring sheet is connected to the PCB through the support and a first terminal extending downward from the base, a magnetic block is installed on the movable end of the spring sheet, and the magnetic block faces a Hall sensor located on the PCB. A movable contact is provided near a front end of the spring sheet, and a stationary contact opposite to the movable contact is provided on the base.

### TECHNICAL FIELD

The present application relates to the field of micro switches, and in particular, to a magnetic induction micro switch with self-calibration.

### BACKGROUND

The existing micro switch technologies mostly adopt a single-path design, that is, a switching state is triggered through single magnetic induction. The micro switch having such a structure is generally triggered by depending on magnetic field induction between a magnetic block and a sensing device, and has the advantages of a simple structure and relatively low cost. However, in practical application, the single-path design based on magnetic induction triggering has certain technical limitations. The magnetic field intensity, direction, and distribution of each magnetic block are difficult to maintain consistent during manufacturing; in addition, during assembly, the positional relationship between the magnetic block and the sensing device often has a slight deviation. The limitation in this design makes it difficult for different micro switches to achieve consistent triggering timing, resulting in deviation in triggering time, manifested as early triggering or delayed triggering of the switch, thereby affecting response time and operation accuracy of devices.

A closer analysis of the causes of this problem reveals that the micro switch triggered by magnetic induction depends on characteristics of a magnetic block, and magnetic field intensity and direction of the magnetic block inevitably exhibit subtle variations during mass production and assembly. Meanwhile, an installation position between the magnetic block and the sensing device is difficult to ensure absolutely precise consistency, and a slight deviation may cause a difference in the induction effect. Therefore, in a case where a micro switch triggered by single-path magnetic induction is used without calibration, an error in switching triggering timing is inevitably caused, affecting synchronization and consistency of the micro switch. In addition, since an existing design lacks an automatic calibration function, such an error is difficult to avoid, which not only affects reliability of operation, but also increases difficulty of subsequent adjustment and maintenance.

Based on the above analysis, development of a magnetic micro switch having a self-calibration function is particularly necessary.

### SUMMARY

To overcome at least one defect in the prior art, an objective of the present application is to provide a magnetic induction micro switch with self-calibration. The micro switch achieves a self-calibration mechanism through addition of an electric path triggered by a contact based on a magnetic path. This design can automatically adjust a relationship between a magnetic block and a sensing device to ensure accuracy and consistency of triggering timing, significantly improve the response speed and synchronization of the micro switch, and reduce requirements in production and installation processes, thereby enhancing reliability and service life of the devices.

To achieve the above objective, the present application discloses a magnetic induction micro switch with self-calibration. The micro switch includes a base provided on a printed circuit board (PCB), a housing cooperating with the base to form an installation cavity, a spring sheet installed in the installation cavity of the base via a conductive support, a limiting frame connected to a movable end of the spring sheet, and an operating member cooperating with the spring sheet and partially extending out of the housing. The spring sheet is connected to the PCB through the support and a first terminal extending downward from the base, a magnetic block is installed on the movable end of the spring sheet, and the magnetic block faces a Hall sensor located on the PCB. A movable contact is provided near a front end of the spring sheet, a stationary contact opposite to the movable contact is provided on the base, and the stationary contact is connected to the PCB via a second terminal. In a case where the operating member moves, the operating member pushes the movable end of the spring sheet and a connected section toward the base, causing the movable contact to engage the stationary contact to conduct electricity and making the magnetic block closer to the Hall sensor. A microcontroller unit (MCU) electrically connected to the Hall sensor and having a data storage function is provided on the PCB, the MCU is directly or indirectly connected to the movable contact and the stationary contact, and an electrical signal is sent to the MCU in a case where the movable contact engages the stationary contact to conduct electricity.

Further, the base and the housing are fixed by a snap-fit connection.

Further, the PCB has at least one output terminal electrically connected to the MCU, and a triggering signal is output externally by the output terminal.

Compared with the prior art, the present application at least has one of the following beneficial effects:

1. Automatic calibration of triggering timing: The present application introduces an electric path triggered by a contact to implement a self-calibration mechanism between the magnetic block and the sensing device, which ensures accuracy of triggering timing and avoids early or delayed triggering caused by magnetic block deviations in conventional single-path designs.

2. Improved synchronization and response speed: The self-calibration function effectively improves synchronization of the micro switch, making triggering timing consistent among a plurality of switches, and significantly enhances the response speed of the device, thereby optimizing operational accuracy.

3. Reduced impact of production and installation errors: The present application automatically adjusts minor installation errors, reduces precision requirements in manufacturing and assembly processes, lowers adjustment difficulty and maintenance cost, and improves overall reliability.

The beneficial effects listed above do not exhaust all benefits. Other potential beneficial effects and detailed technical implementations are further disclosed in the embodiments or other descriptions of the present application.

### BRIEF DESCRIPTION OF DRAWINGS

After reading the following detailed embodiments in conjunction with the drawings, various aspects of the present application are better understood. The positions, dimensions, and ranges of the structures shown in the drawings do not necessarily represent the actual positions, dimensions, or ranges. In the drawings:

FIG. 1 is a schematic diagram of a sectional structure of an embodiment according to the present application.

FIG. 2 is a schematic diagram of a structure of an embodiment according to the present application, in which a housing is removed.

### DETAILED DESCRIPTION OF EMBODIMENTS

The present application is described below with reference to the drawings, and the drawings illustrate several embodiments of the present application. However, it is to be understood that the present application may be embodied in a variety of different ways and is not limited to the embodiments described below. In fact, the embodiments described below are intended to provide a more complete disclosure of the present application and to fully illustrate the scope of the present application to those skilled in the art. It is also to be understood that the embodiments disclosed herein can be combined in various ways to provide additional embodiments.

It is to be understood that, throughout the drawings, like reference numerals refer to like elements. In the drawings, certain feature dimensions may be modified for clarity.

It is to be understood that the terminology used in the specification is intended solely to describe particular embodiments and is not meant to limit the present application. All terms (including technical and scientific terms) used in the specification shall have the meanings commonly understood by those skilled in the art unless otherwise defined. For the sake of brevity and/or clarity, well-known techniques, methods, and devices known to those of ordinary skill in the relevant art may not be described in detail but are intended to be part of the specification where appropriate.

Unless clearly indicated otherwise, the singular forms "a", "an", and "the" used in the specification are intended to include the plural forms as well. The terms "comprise", "include", and "including" used in the specification indicate the presence of the stated features, but do not preclude the presence of one or more other features. The term "and/or" used in the specification encompasses any and all possible combinations of one or more of the listed items.

### Embodiment:

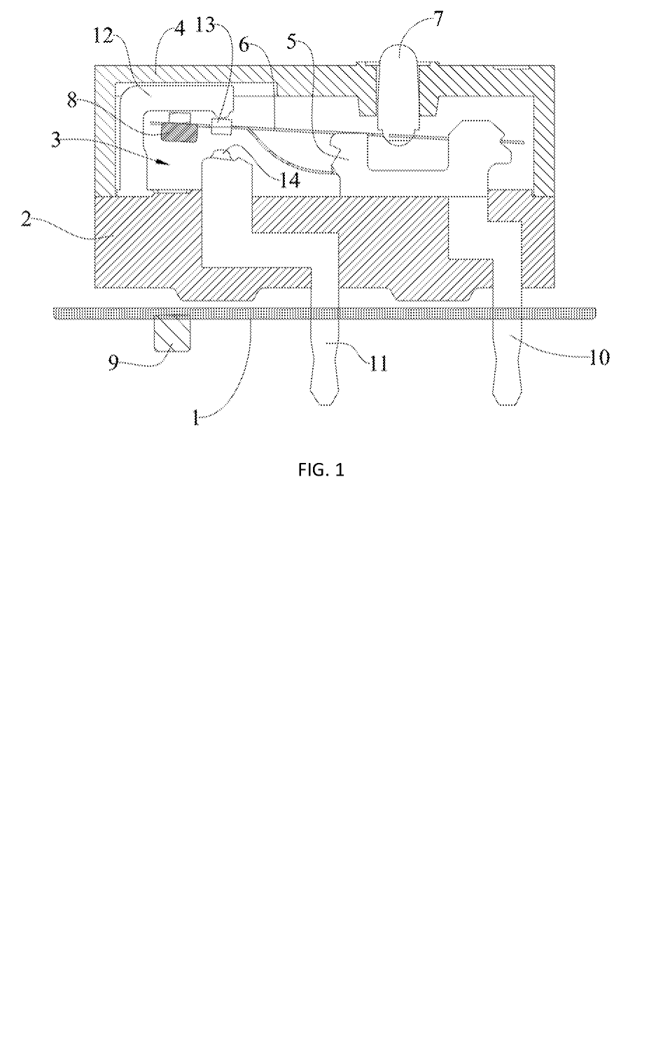

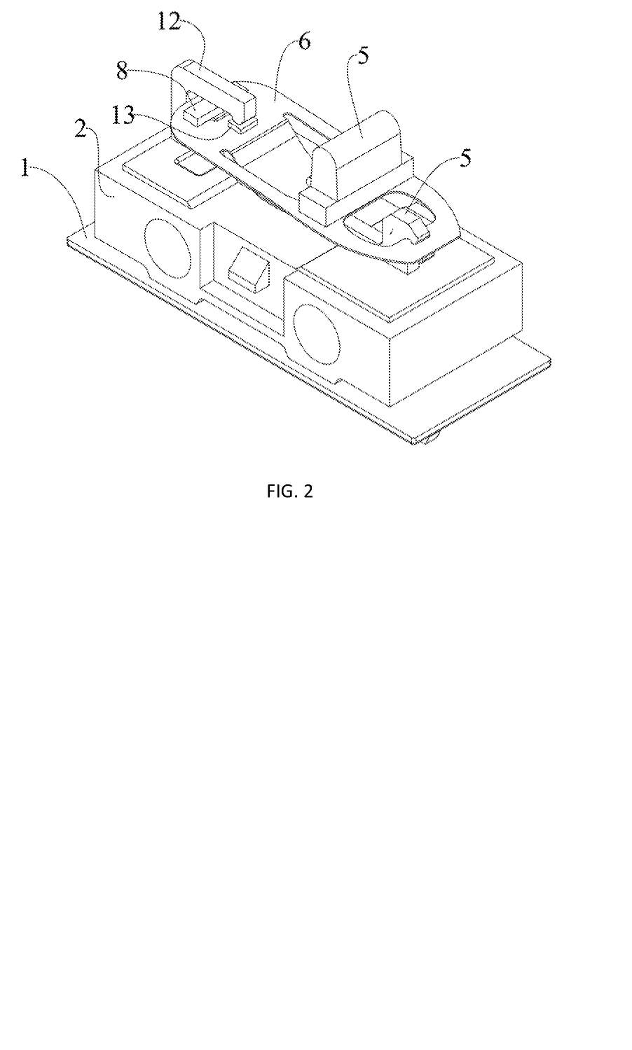

Referring to FIGS. 1 and 2, this embodiment discloses a specific implementation of a magnetic induction micro switch with self-calibration. The overall structure of the magnetic induction micro switch with self-calibration includes a base 2 provided on a PCB 1, a housing 4 cooperating with the base 2 to form an installation cavity 3, a spring sheet 6 installed in the installation cavity 3 via a support 5, a limiting frame cooperating with a movable end of the spring sheet 6, and an operating member 7 cooperating with the spring sheet 6 and partially extending out of the housing 4.

In the above configuration, the base 2 is fixed to the housing 4 by a snap-fit connection, thereby forming the internal installation cavity 3.

In this embodiment, the snap-fit connection between the base 2 and the housing 4 facilitates assembly and disassembly, thereby reducing production and maintenance costs.

The spring sheet 6 is installed on the base 2 via the conductive support 5, and the movable end of the spring sheet 6 cooperates with the limiting frame 12 in an overall inverted L-shape. It should be understood that the spring sheet 6 is made of conductive elastic steel or copper for the purpose of use.

In a specific structure, the spring sheet 6 has a bent shape configured to provide restoring elasticity. The bent portion generally forms an arcuate segment or curved section, which provides a stable and reliable restoring force, allowing the spring sheet to deform under external force and return to the original shape after removal of the external force.

It should also be understood that the spring sheet 6 has two design objectives. First, the spring sheet provides a stable and reliable restoring force with sufficient reset strength, allowing the operating member to return promptly after removal of an external force, thereby ensuring timely and accurate triggering and improving the operational feel of the device. Second, the spring sheet provides electrical conductivity for contact-based triggering.

To achieve the functional objectives of the spring sheet 6, the limiting frame 12 is designed to control the movement range of the spring sheet 6, ensuring that excessive displacement does not occur during operation. The limiting frame also constrains the upper stroke of the spring sheet 6 and provides the spring sheet 6 with a pre-tension, thereby enabling the operating member 7 to reset more quickly and accurately.

In the above configuration, a lower end of the operating member 7 cooperates with the spring sheet 6 and partially extends out of the housing 4 to facilitate external operation.

In the above configuration, the spring sheet 6 is electrically connected to the PCB 1 via the support 5 and a first terminal 10, a magnetic block 8 is mounted on the movable end of the spring sheet 6, and the magnetic block 8 faces a Hall sensor 9 on the PCB 1; and a movable contact 13 is provided near a front end of the spring sheet 6, and a stationary contact 14 cooperating with the movable contact is arranged on the base 2, and the stationary contact 14 is connected to the PCB 1 via a second terminal 11.

In most cases, the Hall sensor 9 is installed on a back side of the PCB 1 using a surface-installation configuration to reduce the overall size of the switch and improve installation stability. Oppositely, the base 2 is installed on a front side of the PCB 1.

During implementation, the movable contact 13 and the stationary contact 14 may be preferably made of silver-plated copper to enhance electrical conductivity and reduce contact resistance.

In most embodiments, the magnetic block 8 is made of neodymium-iron-boron, which has high magnetic performance and can stably cooperate with the Hall sensor 9.

In the above configuration, more specifically, the PCB 1 is provided with a microcontroller unit (MCU, not shown) electrically connected to the Hall sensor 9 and having a data storage function. The MCU is directly or indirectly connected to the stationary contact 13 and the movable contact 14. In a case where the movable contact 13 engages the stationary contact 14 to conduct electricity, the MCU receives an electrical signal and calibrates the magnetic induction triggering parameters based on the received signal.

In a case where the operating member 7 is pressed downward by an external force, the operating member pushes the movable end of the spring sheet 6 toward the base 2. Upon reaching a certain stroke, the movable contact 13 engages the stationary contact 14, thereby closing a switch circuit on the PCB 1. This contact-based conduction not only provides a feedback signal through the electrical path, but also simultaneously adjusts the magnetic induction triggering parameters of the Hall sensor 9 during triggering, achieving a self-calibration effect and reducing cumulative errors in manufacturing and assembly processes.

Specifically, in a case where the movable contact 13 approaches and engages the stationary contact 14, the magnetic block 8 simultaneously moves closer to the Hall sensor 9. Upon the first triggering of the micro switch after manufacture, the opening and closing of the contacts provides a reference value for the magnetic field intensity sensed by the Hall sensor 9. The MCU records the magnetic field intensity sensed by the Hall sensor 9 in this case and stores the strength data as a reference value. During subsequent operations, whenever the magnetic field intensity reaches the reference value, the MCU outputs a triggering signal externally. In this manner, the MCU can automatically calibrate the triggering point, ensuring consistent and accurate triggering timing under different operating conditions.

In application scenarios, such as in input peripherals including mice and game controllers, the operating member 7 serves as a pressing input. In a case where a user presses a button, the operating member 7 is triggered, driving the magnetic block 8 via the spring sheet 6, so that the Hall sensor 9 detects the change in the magnetic field and generates a feedback signal. Since the magnetic induction micro switch in this embodiment is equipped with a self-calibration function, triggering deviations caused by installation errors or mechanical wear can be effectively eliminated, thereby ensuring the accuracy and reliability of the input device during long-term use. In particular, for high-speed responses of game controllers and high-frequency key operations of mice, the self-calibration function of the MCU provides consistent key feedback, thereby improving the user experience and extending the service life of the device.

It should be understood that the circuit design of the PCB 1 as well as the calibration programs and algorithms executed by the MCU in this embodiment do not constitute the claimed features of the present application. The circuit implements the self-calibration function by adopting steps such as magnetic field intensity detection, reference value storage and comparison through signal feedback and processing between the Hall sensor 9 and the MCU. These implementation processes are improvements based on existing mature technologies, including signal acquisition by the Hall sensor 9, computational processing by the MCU, and logical control of the data storage module, all of which are conventional techniques well known to those skilled in the art. Therefore, this part constitutes merely an extension or application of the prior art and does not involve any inventive technical contribution; therefore, this part is not described in further detail in this embodiment.

Although the exemplary embodiments of the present application have been described, those skilled in the art should understand that various modifications and changes can be made to the exemplary embodiments of the present application without departing from the spirit and scope of the present application. Therefore, all such modifications and changes are encompassed within the scope of the present application as defined by the claims. The present application is defined by the appended claims, and equivalents of these claims are also included.

What is claimed is:

1. A magnetic induction micro switch with self-calibration, comprising: a base provided on a printed circuit board (PCB), a housing cooperating with the base to form an installation cavity, a spring sheet installed in the installation cavity of the base via a conductive support, a limiting frame connected to a movable end of the spring sheet, and an operating member cooperating with the spring sheet and partially extending out of the housing, wherein the spring sheet is connected to the PCB through the support and a first terminal extending downward from the base, a magnetic block is installed on the movable end of the spring sheet, and the magnetic block faces a Hall sensor located on the PCB; and a movable contact is provided near a front end of the spring sheet, a stationary contact opposite to the movable contact is provided on the base, the stationary contact is connected to the PCB via a second terminal, in a case where the operating member moves, the operating member pushes the movable end of the spring sheet and a connected section toward the base, causing the movable contact to engage the stationary contact to conduct electricity and making the magnetic block closer to the Hall sensor.

2. The magnetic induction micro switch with self-calibration according to claim 1, wherein a microcontroller unit (MCU) electrically connected to the Hall sensor and having a data storage function is provided on the PCB, the MCU is directly or indirectly connected to the movable contact and the stationary contact, and an electrical signal is sent to the MCU in a case where the movable contact engages the stationary contact to conduct electricity.

3. The magnetic induction micro switch with self-calibration according to claim 1, wherein the base and the housing are fixed by a snap-fit connection.

4. The magnetic induction micro switch with self-calibration according to claim 1, wherein the PCB has at least one output terminal electrically connected to the MCU, and a triggering signal is output externally by the output terminal.
